(19) United States
(12) Patent Application Publication
(10) Pub. No.: US 2025/0197269 A1
(43) Pub. Date: Jun. 19, 2025

(54) STEAM CHAMBER

(71) Applicants: Commissariat à I'Énergie Atomique et aux Énergies Alternatives, Paris (FR); Socpra Sciences et Genie S.E.C, Sherbrooke (CA)

(72) Inventors: Quentin Struss, Grenoble (FR); Amrid Amnache, Sherbrooke (CA); Jean-Philippe Colonna, Grenoble (FR); Perceval Coudrain, Grenoble (FR); Luc Frechette, Sherbrooke (CA); Rajesh Pandiyan, Sherbrooke (CA)

(73) Assignees: Commissariat à I'Énergie Atomique et aux Énergies Alternatives, Paris (FR); Socpra Sciences et Genie S.E.C, Sherbrooke, QC (CA)

(21) Appl. No.: 18/706,343

(22) PCT Filed: Oct. 25, 2022
(86) PCT No.: PCT/EP2022/079721

§ 371 Date: Apr. 30, 2024

(30) Foreign Application Priority Data
Nov. 4, 2021 (FR) 2111712

(51) Int. Cl. C03B 25/02; H05K 7/20

(52) U.S. Cl. CPC C03B 25/02; H05K 7/2029

(57) ABSTRACT

A method of manufacturing a sealed fluid-filled compartment including the following steps: (a) forming at least a first cavity from a first face of a first substrate; (b) positioning a second face of a second substrate opposite the first face of said first substrate; (c) at least partially filling said at least one first cavity with a fluid; (d) bonding said first face of said first substrate to said second face of said second substrate by annealing and simultaneously pressing said first and second substrates together.

### TECHNICAL AREA

The present description relates generally to the cooling of systems, such as mechanical or electronic systems. More specifically, the description concerns a “steam chamber” type cooling device and its manufacturing method.

### PREVIOUS TECHNIQUE

Many systems, such as mechanical or electronic ones, can be subject to overheating phenomena that can damage them or the environment in which they operate. An effective way of countering overheating is to use cooling devices.

There are several types of cooling devices, such as air-conditioning systems, heat pipes, steam chambers, etc. It is common practice to associate a cooling device with a system that is likely to overheat, by positioning it close to a hot spot in that system.

It would be desirable to be able to improve, at least in part, the disadvantages of existing cooling devices and their manufacturing methods.

### SUMMARY OF THE INVENTION

There is a need for more efficient cooling devices.

There is a need for more efficient steam chambers.

There is a need for more efficient manufacturing methods for cooling devices.

There is a need for steam chamber manufacturing methods that are better suited to the mass production of steam chambers.

One embodiment overcomes some or all of the disadvantages of known steam chambers.

One embodiment overcomes some or all of the drawbacks of known steam chamber manufacturing methods.

One embodiment provides a method of manufacturing a sealed fluid-filled compartment comprising the following steps:
(a) forming at least a first cavity from a first face of a first substrate;
(b) positioning a second face of a second substrate opposite the first face of said first substrate;
(c) at least partially filling said at least one first cavity with a fluid;
(d) bonding said first face of said first substrate to said second face of said second substrate by annealing and simultaneously pressing said first and second substrates together.

According to one embodiment, said compartment is a steam chamber, and the fluid is a cooling fluid.

According to one embodiment, the method further comprises a first degassing step for said first and second substrates, performed prior to the filling step.

According to an embodiment, the first degassing step is hot degassing.

According to one embodiment, the method further comprises a second step of degassing the environment of said first and second substrates performed after the filling step.

According to an embodiment, during the second degassing step, the first and second substrates are brought together to limit fluid evaporation.

According to an embodiment, at least one second cavity is formed from the second face of the second substrate.

According to one embodiment, the positioning step comprises aligning said at least one second cavity with said at least one first cavity.

According to one embodiment, during the filling step said at least one first cavity is filled with a volume of cooling fluid greater than the volume of said at least one first cavity.

According to an embodiment, the first and second substrates are made of semiconductor material, silicon or glass.

According to an embodiment, the semiconductor material comprises silicon.

According to an embodiment, the annealing is carried out at a temperature of between about 175 and about 400° C.

According to an embodiment, the annealing is carried out at a temperature of around 200° C.

According to an embodiment, said first and second substrates are pressed with a force of between 0.5 and 2 kN.

According to one embodiment, the cooling fluid is selected from the non-exhaustive group comprising: water, helium, hydrogen, oxygen, nitrogen, sulfide, neon, argon, methane, krypton, mercury, ammonia, acetone, ethane, pentane, heptane, ethanol, methanol, ethylene glycol, toluene, naphthalene, trichlorofluoromethane, dichlorofluoromethane (CHClL₂F, also known by the commercial name Fréon 21), chlorodifluoromethane (CHClF₂, also known by the commercial name Fréon 22), 1,1,2-Trichloro-1,2,2-trifluoroethane (C₂Cl₃F₃, also known by the commercial name Freon 113), the fluid known by the commercial name Flutec PP2, the fluid known by the commercial name Flutec PP9, the fluid known by the commercial name Dowtherm, the fluid known by the commercial name Novec, and derivatives and mixtures of these fluids.

In another embodiment, a steam chamber is manufactured using the method described above.

In another embodiment, a device is provided which is suitable for carrying out the method described above.

According to an embodiment, the device is adapted to simultaneously anneal and press the first and second substrates together with a force of between 0.5 and 2 kN.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1 shows a schematic cross-sectional and functional view of a steam chamber associated with an electronic device;

FIG. 2 shows a schematic cross-sectional view of a substrate used to manufacture steam chambers;

FIG. 3 shows a schematic cross-sectional of a steam chamber using the substrate shown in FIG. 2;

FIG. 4 shows two schematic, partially block-shaped cross-sectional views of a device used to manufacture the steam chambers shown in FIG. 2;

FIG. 5 shows a cross-sectional view illustrating the positioning of the substrate of FIG. 2 in the system of FIG. 4;

FIG. 6 shows a block diagram illustrating the steps involved in a method for manufacturing the steam chambers shown in FIG. 2;

FIG. 7 shows four cross-sectional views illustrating an example of a method for bonding two substrates that can be used in the method shown in FIG. 6;

FIG. 8 shows a cross-sectional view of a cavity with which a variant of the method described in FIG. 6 can be used;

FIG. 9 shows, schematically, a cross-sectional view of another cavity with which a variant of the method described in FIG. 6 can be implemented; and

FIG. 10 shows a schematic cross-section of a micro-battery which can be used to implement a variant of the method described in FIG. 6.

### DESCRIPTION OF EMBODIMENTS

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10%, and preferably within 5%.

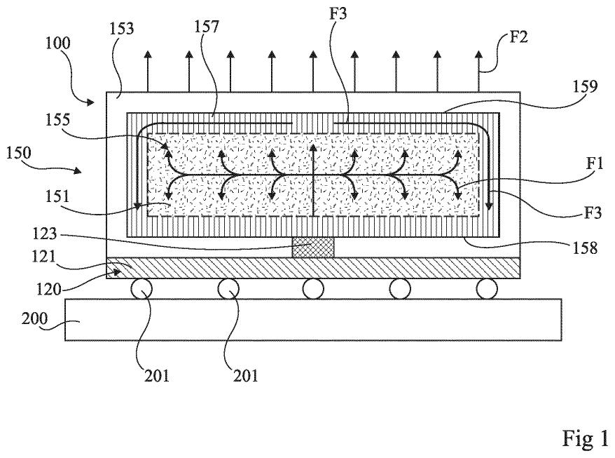

FIG. 1 is a schematic, functional cross-sectional view of an electronic system 100 comprising a steam chamber 150.

The electronic system 100 is mounted on a substrate 200, for example, via connection balls 201. Substrate 200 is, for example, a solid substrate, or a printed circuit board, etc.

The electronic system 100 consists of an electronic device 120 and the steam chamber 150.

The electronic device 120 is of any type, and may comprise one or more components, one or more circuits, e.g. one or more printed circuits, and so on. These components are represented in FIG. 1 by a layer 121. The device 120 also comprises at least one hot spot 123, i.e. an area likely to generate high heat, or an area likely to overheat. This hot spot 123 may correspond to a part of a component, an entire component, a set of components, a conductor, etc. The hot spot 123 is represented in FIG. 1 by a block 123.

The steam chamber 150 comprises a cavity 151 formed in a substrate 153. Cavity 151 is filled with cooling fluid 155. A capillary return structure 157 is arranged on the walls of cavity 151.

The steam chamber 150 is arranged to help cooling the hot spot 123 of the device 120. Thus, a lower face 158 of cavity 151 is positioned against the hot spot 123 of electronic device 120, this face is called evaporator. An upper face 159 of the electronic device 120, opposite face 158, is called the condenser. The upper face 159 may be attached to a heat sink not shown in FIG. 1.

The steam chamber 150 operates as follows. At rest, i.e. when the hot spot 123 is not generating heat, the fluid 155 is in equilibrium between its gaseous phase, or vapor phase, and its liquid phase. When the hot spot 123 generates heat, the fluid 155 directly adjacent to the hot spot 123 evaporates, creating a vapor movement within the cavity 151. More specifically, the vapor-phase fluid 155 moves away from face 158, for example towards face 159, which is symbolized in FIG. 1 by an arrow F1. Once vapor-phase fluid 155 reaches cavity face 159, it encounters return structure 157 by capillary action and condenses back into its liquid phase. Heat is thus released on the condenser side, for example into a heat sink, a phenomenon symbolized by arrows F2. The temperature of fluid 155 then decreases and it returns to its initial position, following, for example, the direction of arrows F3.

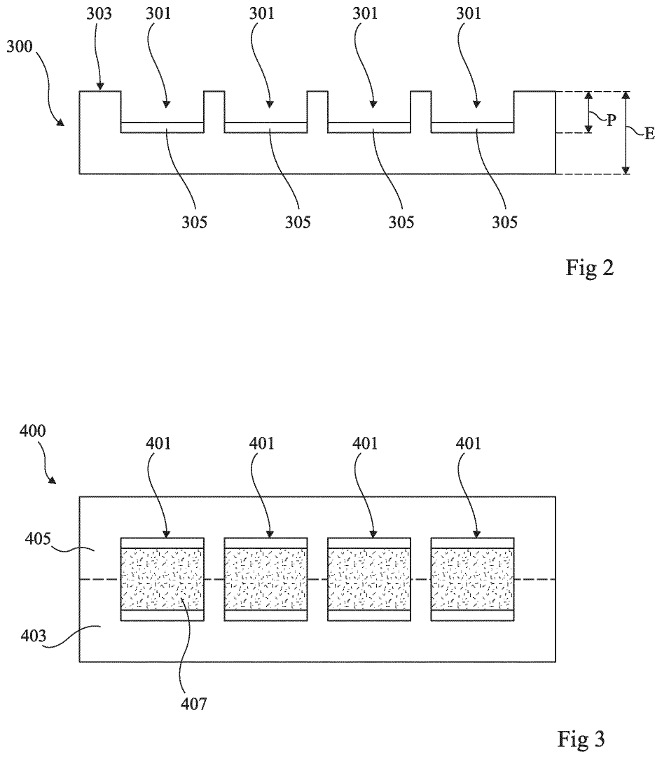

FIG. 2 is a cross-sectional view of an embodiment of a substrate 300. The substrate 300 is, for example, made of a semiconductor material, such as a material comprising silicon. Alternatively, substrate 300 may be made of glass.

Substrate 300 is intended for the manufacture of steam chambers, and has undergone various preparatory operations for this purpose.

More particularly, cavities 301 are formed from an upper face 303 of the substrate 300, cach cavity 301 being intended to form, entirely or partially, the cavity of a steam chamber of the type described in relation to FIG. 1. The cavities 301 may be obtained by various masking and etching methods.

In addition, capillary return structures 305 are formed in the bottom of the cavities 301. According to an embodiment, capillary return structures 305 are also formed on the side walls of cavities 301. According to one example, the 305 capillary return structure is a so-called “wick” structure which may comprise porous structures such as grooves or metal foams, such as copper foams having minimum pore sizes of the order of 1 μm. According to one example, the capillary return structure can be a porous structure made from a substrate, for example of copper or silicon, in which grooves, for example of the order of 1 μm to 1 mm in width, and/or columns, for example of the order of 1 μm to 1 mm in width, are formed.

According to an embodiment, substrate 300 may have a thickness E of between 200 and 300 μm, for example of the order of 225 μm. According to one example, the substrate may have been thinned to present such a thickness. Cavities 301 can have a depth P of between 50 and 100 μm, for example of the order of 75 μm. These dimensions are only an example, and the person skilled in the art will know how to adapt them to the dimensions of the steam chambers to be manufactured.

FIG. 3 is a cross-sectional view of an embodiment of a system 400 comprising steam chambers 401. More specifically, in FIG. 3, the 400 system comprises four identical 401 steam chambers, apart from manufacturing variations.

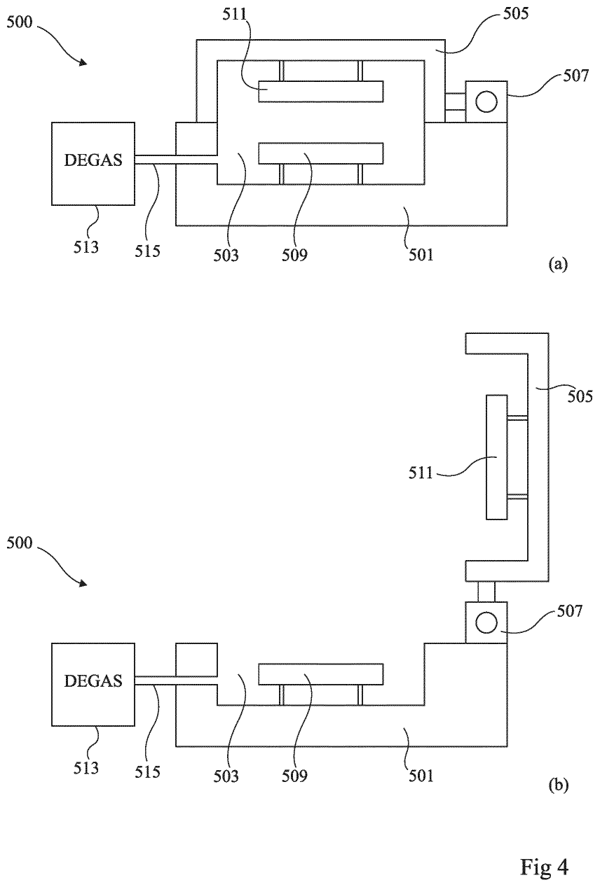

The 400 system is formed from two similar substrates 403 and 405 of the type of substrate 300 described in relation to FIG. 2. Thus, cach substrate 403, 405 comprises cavities formed from one of its faces. To form the system 400, the cavities of substrates 403 and 405 are filled with a cooling fluid 407 and then the substrates 403 and 405 are bonded together by a gluing method. More specifically, the two faces from which the cavities of substrates 403 and 405 extend are bonded, and the cavities of substrates 403 and 405 are aligned. Each enclosure formed by the bonding of a substrate cavity 403 and a substrate cavity 405 is intended to form a steam chamber. The filling and bonding methods used to form the 400 system are described in more detail in relation to FIGS. 4 to 6.

According to one embodiment, the cooling fluid 407 is selected from the non-exhaustive group comprising: water, helium, hydrogen, oxygen, nitrogen, sulfide, neon, argon, methane, krypton, mercury, ammonia (NH₃), acetone (C₃H₆O), ethane (C₂H₆), pentane (C₅H₁₂), heptane (C₇H₁₆), ethanol (C₂H₅OH), methanol (CH₃OH), ethylene glycol (C₂H₆O₂), toluene (C₇H₈), naphthalene (C₁₀H₈), trichlorofluoromethane (CCl₃F, also known under the commercial name Fréon 11), dichlorofluoromethane (CHCl₂F, also known under the commercial name Fréon 21), chlorodifluoromethane (CHClF₂, also known by the commercial name Fréon 22), 1,1,2-trichloro-1,2,2-trifluorocthane (C₂C₃F₃, also known by the commercial name Freon 113), the fluid known by the commercial name Flutec PP2, the fluid known under the commercial name Flutec PP9, the fluid known under the commercial name Dowtherm, the fluid known under the commercial name Novec, and derivatives and mixtures of these fluids.

According to an embodiment, substrates 403 and 405 may have cavities of different depths. In another embodiment, one of the two substrates 403 or 405 may have no cavities.

FIG. 4 shows two cross-sectional views (a) and (b) of a device 500 that can be used to manufacture the system shown in FIG. 3. Views (a) and (b) illustrate two different positions of device 500.

The device 500 comprises a base 501 comprising an enclosure 503 covered by a lid 505. The dimensions of the enclosure 503 are large enough for it to contain at least one system of the type of system 400 described in relation to FIG. 3. According to an embodiment, the cover 505 is used to hermetically seal the enclosure 503. Lid 505 is attached to base 501 by fastening means 507. In one example, attachment means 507 is an articulated arm adapted to pivot lid 505 relative to base 501. Views (a) and (b) illustrate two examples of the position of cover 505. More specifically, view (a) of FIG. 4 illustrates the case where lid 505 is closed, and view (b) illustrates the case where lid 505 is open.

The device 500 further comprises a holder 509 arranged in the enclosure 503, and a holder 511 attached to the lid 505. The supports 509 and 511 are adapted to receive all types of substrates, such as, for example, substrates of the type of substrate 300 described in connection with FIG. 2. Holders 509 and 511 include hooking means, not shown in FIG. 4, for gripping a substrate. These means of attachment are, for example, mechanical means of attachment such as hooks, an adhesive layer deposited on the surface of the support 509, 511, vacuum suction, etc. The lateral position and height position of supports 509 and 511, relative to enclosure 503 and lid 505 respectively, are adjustable by means not shown in FIG. 4. According to an embodiment, supports 509 and 511 are further adapted to apply pressure, for example with a force less than or equal to 2 kN.

The 500 unit further comprises a 513 device (DEGAS) adapted to evacuate the 503 enclosure once the 505 lid is in the closed position (view (a)). Device 513 is connected to the enclosure by a duct 515 formed in base 501. According to one example, device 513 is a vacuum pump, for example, associated with a cold trap. According to one example, duct 515 may be connected to device 513 via a sealed valve. Alternatively, duct 515 may be connected to one or more other gas transmission and/or treatment devices.

The 500 unit also includes heating means, not shown in FIG. 4, adapted to perform thermal annealing in the 503 enclosure.

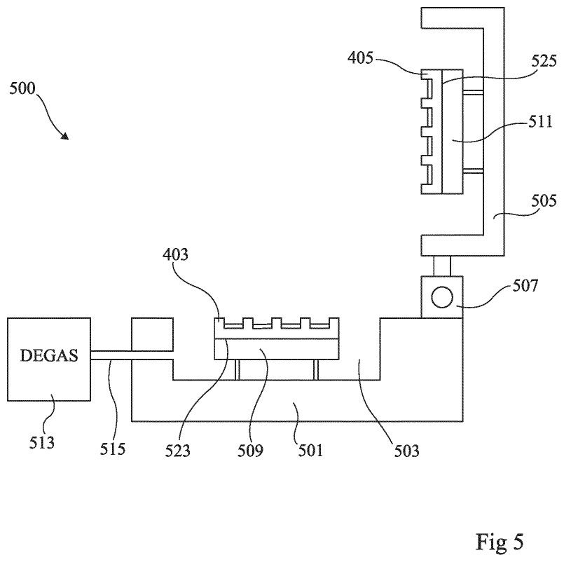

FIG. 5 is a cross-sectional view illustrating the placement of the two substrates 403 and 405 on the supports 509 and 511 of the device 500 described in relation to FIG. 4.

To position the substrates 403 and 405 on the supports 509 and 511 of the device 500, the cover 505 is placed in the open position described in relation to view (b) of FIG. 4.

The substrate 403 is positioned on the support 509. In particular, the underside 523 of substrate 403 is positioned against support 509. Substrate 403 is held against support 509 by means of support 509 hooking means. Similarly, substrate 405 is positioned on support 511, and more particularly, its lower face 525 is arranged against support 511. The substrate 405 is held against the support 511 by the support 511 hooking means.

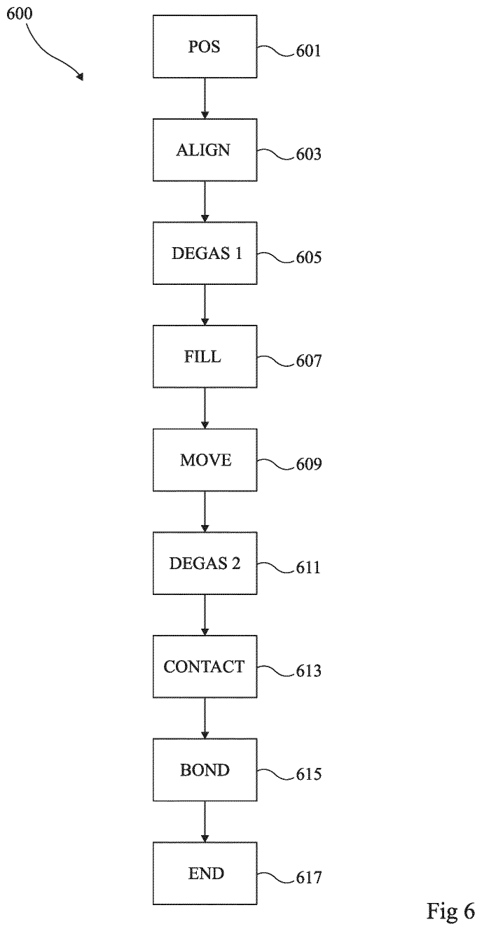

FIG. 6 is a block diagram illustrating a filling and bonding method leading to the formation of the 400 system shown in FIG. 3.

As previously described, the system 400 consists of two substrates 403 and 405 of the type of substrate 300 described in connection with FIG. 2. To implement the method described in relation to FIG. 6, the device 500 described in relation to FIGS. 4 and 5 is used.

In a step 601, symbolized by a “POS” block, the substrates 403 and 405 are positioned on the supports 509 and 511 of the device 500, as described in relation to FIG. 5. To do this, the lid 505 of the device 500 is opened. According to one example, substrate 403 is attached to support 509 and substrate 405 is attached to support 511.

In a step 603, symbolized by an “ALIGN” block, the lateral and height positions of supports 509 and 511 are modified to align substrates 403 and 405. To do this, the lid 505 of the device 500 is closed so as to position the supports 509 and 511 parallel to and facing each other. This position of device 500 is described in relation to view (a) of FIG. 4. Substrates 403 and 405 are considered to be aligned once the openings of the cavities of substrates 403 and 405 are aligned with each other to obtain a structure of the type of system 400 described in relation to FIG. 4. At this stage, substrates 403 and 405 are only aligned and not brought into contact.

In a step 605, symbolized by a “DEGAS 1” block, substrates 403 and 405 are degassed, for example hot degassed. Degassing the substrates 403 and 405 removes gaseous chemical species that may be absorbed by the material of the substrates 403 and 405. These chemical species could render the bonding of the two substrates 403 and 405 less effective. The lid 505 hermetically seals the enclosure 503 of the device 500. For this degassing step, the device 513 adapted to evacuate the enclosure 503 and the means for heating the enclosure 503 are started. In fact, degassing of this type is carried out at high temperature, for example at a temperature of between 100 and 200° C.

In a step 607, symbolized by a “FILL” block, the substrate cavities 403 and 405 are filled with the cooling lfuid 407 described in relation to FIG. 3. Several different filling methods can be implemented here.

A first filling method involves opening the lid 505 of the device 500, then filling the cavities as a unit or together with a volume of cooling fluid greater than the volume of cooling fluid required to operate the steam chamber. Unitary filling of the cavities can be achieved using a filling device such as a syringe or micro-syringe, the dimensions of which are adapted to the dimensions of the cavities. Common filling of the cavities can be achieved using a filling device consisting, for example, of several syringes or micro-syringes arranged in parallel. In this method, the cooling fluid is introduced in its liquid phase after being degassed.

A second filling method that can be used is similar to the first method, but differs in that the cooling fluid is placed in the cavities in its solid phase after first being purified and degassed.

A third filling method that can be used is similar to the first and second methods, but differs in that the cooling fluid is arranged in the cavities in the form of a hydrogel after having first been purified and degassed. A hydrogel is a gel in which water is used as a blowing agent, a gel being a network of solid elements diluted in a solvent.

In a step 609, symbolized by a “MOVE” block, substrates 403 and 405 are brought closer together without being brought into contact. To achieve this, the height position of the device supports 509 and 511 is altered. In particular, substrates 403 and 405 are positioned as close as possible to each other according to the adjustment of supports 509 and 511.

In a step 611, symbolized by a “DEGAS 2” block, the enclosure 503 of the device 500 is degassed. To do this, lid 505 seals enclosure 503, and the gases present are evacuated via duct 515 by device 513. As the substrates have been positioned as close together as possible, the cooling fluid in their cavities cannot evaporate completely.

According to an embodiment, a reservoir containing the cooling fluid is placed in the enclosure 503, for example during the filling stage of step 607, to enable the enclosure atmosphere to be saturated with the cooling fluid. In this case, it is not necessary to evacuate the enclosure 503.

At step 613, symbolized by a “CONTACT” block, substrates 403 and 405 are brought into contact by adjusting the height position of supports 509 and 511.

According to an embodiment, to enable residual gases in the cavities of substrates 403 and 405 to be degassed, substrates 403 and 405 can initially be spaced apart by a small distance, for example of the order of 1 mm, and then rapidly brought into contact. In this way, the last residual gases trapped in the cavities can be eliminated by drawing air outwards from the cavities.

In a step 615, symbolized by a “BOND” block, substrates 403 and 405 are bonded together to form the system 400 described in relation to FIG. 3. To achieve this, substrates 403 and 405 are mechanically pressed together. At the same time, annealing is carried out in chamber 503. The use of annealing during bonding consolidates the bond between the two substrates 403, 405 by forming covalent bonds between the chemical elements of the substrate materials 403 and 405, which is not possible at low temperatures. The pressure force applied to the two substrates and the annealing temperature are determined by the material of the substrates 403 and 405 and the type of cooling fluid 407 used. According to an example, when substrates 403 and 405 are made of silicon and the cooling fluid is water:
the pressure force applied to both substrates 403 and 405 is less than 2 kN, for example between 0.5 and 2 kN; and
annealing is carried out at a temperature of between 175 and 400° C., for example 200° C.

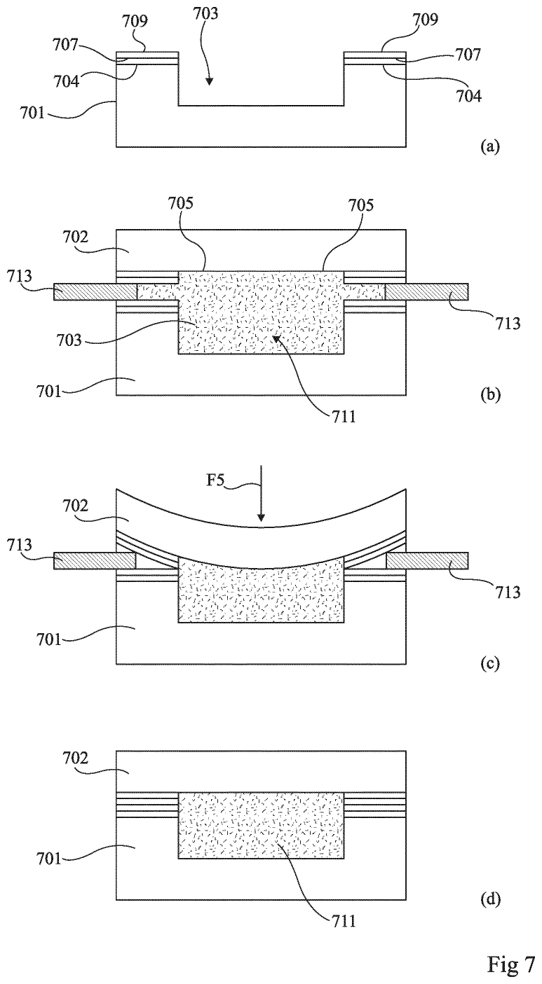

FIG. 7 shows in greater detail an example of a gold-gold (Au—Au) bond used to bond substrates 403 and 405.

At step 617, symbolized by an “END” block, the bonding method is completed, and the manufacturing method of the system 400 is finished. The steam chambers 401 of the system can be individualized, for example by sawing.

An advantage of the method described in relation to FIG. 6 is that it enables steam chambers directly filled with cooling fluid to be formed, hermetically sealed and without fragile zones due to an external filling method, such as, for example, a filling achieved by forming an access hole to the cavity.

Another advantage of the method described here is that it enables a strong bond to be formed between the two substrates, since it achieves a bond by simultaneously annealing and pressing the substrates together.

FIG. 7 shows schematically two cross-sectional views (a), (b), (c) and (d) illustrating the steps involved in a Gold-Gold (Au—Au) bonding method between two substrates 701 and 702.

Gold-gold (Au—Au) bonding is generally used to bond two sides of two substrates, e.g. silicon semiconductor substrates. The substrates 701 and 702 considered here are of the same type as substrates 403 and 405 described in connection with FIG. 3, and more particularly of the same material as substrates 403 and 405.

In the example shown in FIG. 7, substrate 701 comprises a cavity 703 formed from its top face 704. No cavity is formed in substrate 702, one of whose faces 705 is intended to be bonded to the top face 704 of substrate 701, so as to close cavity 703. Alternatively, a cavity may be present in substrate 702.

View (a) shows a substrate 701 deoxidation step. During this step, substrate 701 is exposed to a deoxidation solution, such as hydrogen fluoride (HF).

View (a) also shows a step for depositing a bonding layer 707 on the top surface 704 of substrate 701. The bonding layer 707 is, for example, a titanium layer deposited by evaporation. According to one example, the adhesion layer 707 has a thickness of between 1 and 10 nm, for example of the order of 5 nm.

View (a) also shows a step in which a layer of gold (Au) 709 is deposited by evaporation. According to one example, the 709 gold layer has a thickness of between 10 and 20 nm, for example of the order of 15 nm.

The thicknesses of layers 707 and 709 are not shown to scale in FIG. 7.

The steps shown in view (a) are, in parallel, also applied to the substrate 702, and more specifically its face 705. The application of these steps to substrate 702 is not shown in FIG. 7.

View (b) shows a step for filling the cavity 703 of substrate 701 with a filling fluid 711. The filling fluid 711 is, for example, a cooling fluid of the type of cooling fluid 407 described in relation to FIG. 3.

View (b) also shows a step for positioning substrate 702 on substrate 701. Substrate 702 is positioned on substrate 701 so as to have their faces 704 and 705 facing each other, and more particularly the gold layers covering them facing each other. Furthermore, substrates 701 and 702 are separated by removable spacers 713 and are therefore not in direct contact. According to one example, the spacers 713 are razor blades, with a thickness of the order of 100 μm.

View (c) shows a step in which the assembly consisting of substrates 701 and 702 is evacuated to remove the last non-condensable gases present in cavity 703. As substrate 702 is made of a relatively flexible material, such as silicon, it bends. According to one example, during this vacuum stage, the temperature is always equal to room temperature.

View (c) also shows the application of a vertical force, symbolized by arrow F5 in view (c), to bring the gold layers deposited on faces 704 and 705 of substrates 701 and 702 into contact at certain points. Spacers 713 are still retained. This step corresponds in part to the implementation of step 615 described in relation to FIG. 6.

View (d) shows a bonding finalization step, where bonding has begun at the application of force F5, propagates to the lateral ends of substrates 701 and 702 and the spacers are removed, for example manually. A rest step is then carried out before a final annealing. Substrates 701 and 702 are hermetically bonded. This step corresponds in part to the implementation of step 615 described in relation to FIG. 6.

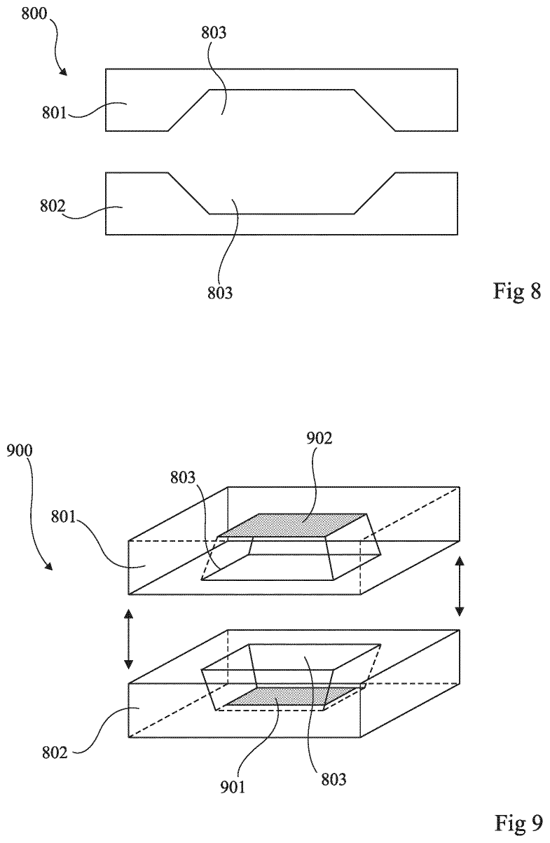

The methods described in relation to FIGS. 6 and 7 are described here for the realization of a steam chamber, but they can be used for the more general realization of any hermetically sealed fluid-filled compartment. Further examples of such compartments are described in relation to FIGS. 8 to 10.

FIG. 8 shows a highly schematic cross-sectional view of a general example of a compartment 800 that can be hermetically or semi-hermetically sealed as described above.

Like the steam chambers 401 described in relation to FIG. 3, compartment 800 is formed from two plates 801 and 802 hermetically or semi-hermetically bonded together. A cavity 803 is formed from a face of at least one of the two plates 801 or 802. In FIG. 8, the two plates have cavities 803 facing each other during the bonding method. According to one example, the plates 801 and 802 are semiconductor substrates, for example made of silicon, or glass substrates.

FIG. 9 shows a schematic perspective view of a 900 variant of the 800

compartment, in which the cavities 803 have a porous membrane 901 at the bottom, enabling exchange between the encapsulated fluid and the external environment.

Such a compartment 900 can be used to implement a medical or paramedical device, such as a bio-capsule.

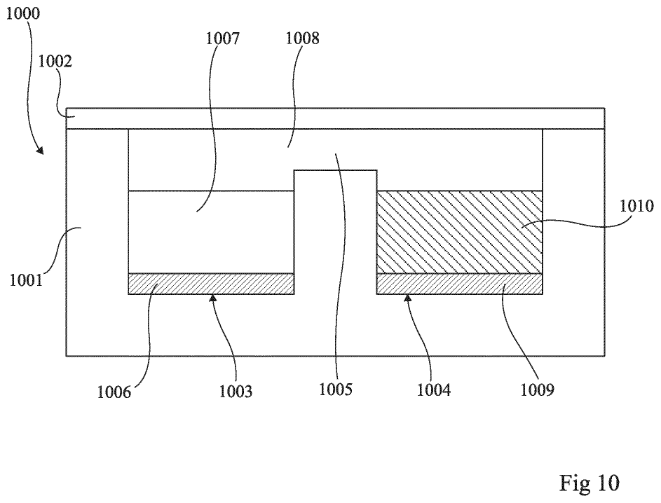

FIG. 10 shows a highly schematic cross-sectional view of a 1000 battery obtainable using the methods described in FIGS. 6 and 7. In one example, the 1000 battery is a microbattery.

The 1000 battery is formed from two substrates 1001 and 1002. In substrate 1001, twin cavities 1003 and 1004 are formed, connected by a trench 1005. Substrate 1002 is bonded to substrate 1001 to close cavities 1003 and 1004 and trench 1005.

According to one example, cavity 1003 is the anode of battery 1000, and cavity 1004 is the cathode of battery 1000.

The cavity 1003 is filled with:
a first layer 1006 of materials forming an electrode;
a second layer 1007 of materials forming the anode of the battery 1000; and
a third layer 1008 of materials forming the electrolyte of the battery 1000.

The third layer 1008 overflows from cavity 1003, into trench 1005 and into cavity 1004. Thus, cavity 1004 is filled by:
a first layer 1009 of materials, for example identical to layer 1006, forming an electrode;
a second layer 1008 of materials forming the cathode of the battery 1000; and
a third layer 1008 of materials forming the electrolyte of the battery 1000.

Bonding of substrates 1001 and 1002, and filling of cavities 1003 and 1004 can be achieved by a method similar to those described in relation to FIGS. 6 and 7.

Various embodiments and variants have been described. The person skilled in the art will understand that certain features of these various embodiments and variants could be combined, and other variants will become apparent to the person skilled in the art. In particular, the device described in connection with FIG. 4 is an example of a device used to implement the method of FIG. 6, other devices known to the person skilled in the art may be used.

Finally, the practical implementation of the embodiments and variants described herein is within the capabilities of those skilled in the art based on the functional description provided hereinabove.

1. A method for manufacturing a sealed fluid-filled compartment comprising the following successive steps:
(a) forming at least one first cavity from a first face of a first substrate;
(b) positioning a second face of a second substrate opposite the first face of said first substrate;
(c) at least partially filling said at least one first cavity with a fluid;
(d) bonding said first side of said first substrate to said second side of said second substrate by annealing and simultaneously pressing said first and second substrates together.

2. Method according to claim 1, wherein said compartment is a steam chamber, and the fluid is a cooling fluid.

3. Method according to claim 1, further comprising a first degassing step (e) of said first and second substrates performed prior to filling step (c).

4. Method according to claim 3, in which the first degassing step (e) is hot degassing.

5. A method according to claim 1, further comprising a second step (f) of degassing the environment of said first and second substrates performed after step (c) of filling.

6. Method according to claim 5, in which, during the second degassing step (f), the first and second substrates are brought close together to limit evaporation of the fluid.

7. Method according to claim 1, in which at least one second cavity is formed from the second face of the second substrate.

8. A method according to claim 7, wherein positioning step (b) comprises aligning said at least one second cavity with said at least one first cavity.

9. Method according to claim 1, wherein, during filling step (c) said at least one first cavity is filled with a volume of cooling fluid greater than the volume of said at least one first cavity.

10. Method according to claim 1, in which the first substrate and the second substrate are made of a semiconductor material, silicon or glass.

11. Method according to claim 10, wherein the semiconductor material comprises silicon.

12. Method according to claim 1, wherein the annealing is carried out at a temperature of between about 175 and about 400° C.

13. Method according to claim 12, in which the annealing is carried out at a temperature of the order of 200° C.

14. Method according to claim 1, wherein the pressing of said first and second substrates is carried out with a force of between 0.5 and 2 kN.

15. Method according to claim 2, wherein the cooling fluid is selected from the non-exhaustive group comprising: water, helium, hydrogen, oxygen, nitrogen, sulfide, neon, argon, methane, krypton, mercury, ammonia (NH₃), acetone (C₃H₆O), ethane (C₂H₆), pentane (C₅H₁₂), heptane (C₇H₁₆), ethanol (C₂H₅OH), methanol (CH₃OH), ethylene glycol (C₂H₆O₂), toluene (C₇H₈), naphthalene (C₁₀H₈), trichlorofluoromethane (CClL₃F, also known under the commercial name Fréon 11), dichlorofluoromethane (CHClL₂F, also known under the commercial name Fréon 21), chlorodifluoromethane (CHClF₂, also known under the commercial name Fréon 22), 1,1,2-trichloro-1,2,2-trifluoroethane (C₂Cl₃F₃, also known under the commercial name Freon 113), the fluid known under the commercial name Flutec PP2, the fluid known under the commercial name Flutec PP9, the fluid known under the commercial name Dowtherm, the fluid known under the commercial name Novec, and derivatives and mixtures of these fluids.

16. Steam chamber manufactured using the method of claim 1.

17. Apparatus suitable for carrying out the method according to claim 1.

18. Apparatus according to claim 17, adapted to simultaneously anncal and press the first substrate and the second substrate against each other with a force of between 0.5 and 2 kN.
